(19) United States
(12) Patent Application Publication
(10) Pub. No.: US 2026/0114026 A1
(43) Pub. Date: Apr. 23, 2026

(54) SEMICONDUCTOR DEVICE IN FORKSHEET TRANSISTOR STRUCTURE INCLUDING PASSIVE DEVICE AND BSPDN STRUCTURE

(71) Applicant: SAMSUNG ELECTRONICS CO., LTD., Suwon-si (KR)

(72) Inventors: Hyo Jong Shin, Mechanicville, NY (US); Edward Namkyu Cho, Slingerlands, NY (US); Kibyung PARK, Watervliet, NY (US); Kang-ill Seo, Springfield, VA (US)

(73) Assignee: SAMSUNG ELECTRONICS CO., LTD., Suwon-si (KR)

(21) Appl. No.: 19/233,432

(22) Filed: Jun. 10, 2025

Related U.S. Application Data
(60) Provisional application No. 63/710,989, filed on Oct. 23, 2024.

(51) Int. Cl. H10D 84/40; H10D 84/01

(52) U.S. Cl. CPC H10D 84/409; H10D 84/0109

(57) ABSTRACT

Provided is a semiconductor device including: a semiconductor wall having a 1^{st} polarity; a 1^{st} semiconductor layer on a 1^{st} side of the semiconductor wall along a 2^{nd} direction intersecting a 1^{st} direction, the 1^{st} semiconductor layer having the 1^{st} polarity or a 2^{nd} polarity opposite to the 1^{st} polarity; and a backside isolation structure below the semiconductor wall and the 1^{st} semiconductor layer along a 3^{rd} direction intersecting the 1^{st} direction and the 2^{nd} direction, wherein the backside isolation structure comprises a 1^{st} insulation material.

### CROSS-REFERENCE TO RELATED APPLICATION

This application is based on and claims priority from U.S. Provisional Application No. 63/710,989 filed on Oct. 23, 2024 in the U.S. Patent and Trademark Office, the disclosure of which is incorporated herein in its entirety by reference.

### BACKGROUND

### 1. Field

Apparatuses and methods consistent with the disclosure relate to a semiconductor device in a forksheet transistor structure that includes a passive device and a bipolar junction transistor (BJT).

### 2. Description of Related Art

A nanosheet transistor is characterized by a plurality of nanosheet layers vertically stacked on a substrate as a channel structure and a gate structure surrounding all four surfaces of each of the nanosheet layers. The nanosheet transistor is known to allow a better control of current and enable a higher device density than a field-effect transistor (FinFET). The nanosheet transistor is also referred to as gate-all-around (GAA) transistor, or as a multi-bridge channel field-effect transistor (MBCFET).

The nanosheet transistor has evolved into a forksheet transistor which enables further miniaturization of a semiconductor device. The forksheet transistor may take a form of a combination of two nanosheet transistors with an isolation wall therebetween isolating the two nanosheet transistors from each other. Nanosheet channel layers of each nanosheet transistor in the forksheet transistor may be formed at each side of the isolation wall and pass through a gate structure of the nanosheet transistor at each side of the isolation wall.

In the meantime, in a semiconductor device, bipolar junction transistors (BJTs), and passive devices such as diodes may be formed in a substrate on which field-effect transistors are formed in order to achieve device density. However, formation of the BJTs and the passive devices in the substrate is limited in a semiconductor device including a backside power distribution network (BSPDN) structure. This is because the substrate of the semiconductor device may be removed and replaced by a backside isolation structure to form the BSPDN structure such as backside contact plugs and backside metal lines therein. A semiconductor device formed of forksheet transistors may have the same challenge when a substrate of the semiconductor device is replaced by a backside isolation structure to form the BSPDN structure.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

The disclosure provides various embodiments of a semiconductor device in a forksheet transistor structure including a BSPDN structure in which PN diodes and the BJTs can be formed on a front side of the forksheet transistor structure. For example, an isolation wall for a forksheet transistor is replaced with a semiconductor wall as a p-type or n-type region of a PN diode or a base of a BJT, and further, source/drain patterns for the forksheet transistor are formed as semiconductor layers of a p-type or n-type region of the PN diode or an emitter and a collector of the BJT. The disclosure also provides a method of manufacturing this semiconductor device.

According to one or more embodiments, there is provided a semiconductor device which may include: a semiconductor wall having a 1^{st} polarity; a 1^{st} semiconductor layer on a 1^{st} side of the semiconductor wall along a 2^{nd} direction intersecting a 1^{st} direction, the 1^{st} semiconductor layer having the 1^{st} polarity or a 2^{nd} polarity opposite to the 1^{st} polarity; and a backside isolation structure below the semiconductor wall and the 1^{st} semiconductor layer along a 3^{rd} direction intersecting the 1^{st} direction and the 2^{nd} direction, wherein the backside isolation structure includes a 1^{st} insulation material.

According to one or more embodiments, there is provided a semiconductor device which may include: a semiconductor wall having a 1^{st} polarity; a 1^{st} semiconductor layer on a 1^{st} side of the semiconductor wall along a 2^{nd} direction intersecting a 1^{st} direction, the 1st semiconductor layer having the 1^{st} polarity or a 2^{nd} polarity opposite to the 1^{st} polarity; and a diffusion break structure including a 1^{st} insulation material at a side of the 2st semiconductor layer and the semiconductor wall along the 1^{st} direction.

According to one or more embodiments, there is provided a method of manufacturing a semiconductor device, the method including: forming a 1^{st} semiconductor layer having a 1^{st} polarity or a 2^{nd} polarity opposite to the 1^{st} polarity; forming a semiconductor wall having the 1^{st} polarity at a side of the 1^{st} semiconductor layer along a 2^{nd} direction intersecting a 1^{st} direction; and forming a backside isolation structure below the semiconductor wall and the 1^{st} semiconductor layer along a 3^{rd} direction intersecting the 1^{st} direction and the 2^{nd} direction, wherein the backside isolation structure comprises a 1^{st} insulation material.

According to one or more embodiments, there is provided a semiconductor device which may include: a semiconductor substrate; a semiconductor wall on the semiconductor substrate, the semiconductor wall having a 1^{st} polarity; and a 1^{st} semiconductor layer on a 1^{st} side of the semiconductor wall along a 2^{nd} direction intersecting a 1^{st} direction, the 1^{st} semiconductor layer having the 1^{st} polarity or a 2^{nd} polarity opposite to the 1^{st} polarity.

### BRIEF DESCRIPTION OF DRAWINGS

Example embodiments of the disclosure will be more clearly understood from the following detailed description taken in conjunction with the accompanying drawings.

FIGS. 1A-1C illustrate a semiconductor device including a forksheet transistor in which a BSPDN structure is formed, according to one or more embodiments.

FIGS. 2A-2C illustrate a semiconductor device in a forksheet transistor structure in which passive devices are formed on a backside isolation structure, according to one or more embodiments.

FIGS. 3A-3C illustrate a semiconductor device in a forksheet transistor structure in which BJTs are formed on a backside isolation structure, according to one or more embodiments.

FIG. 4 illustrates a semiconductor device in a forksheet transistor structure in which a forksheet transistor, passive devices and BJTs are formed on a backside isolation structure, according to one or more embodiments.

FIGS. 5A-5C illustrate a semiconductor device in a forksheet transistor structure in which passive devices are formed on a backside isolation structure, according to one or more embodiments.

FIGS. 6A-6C illustrate a semiconductor device in a stacked forksheet transistor structure in which passive devices are formed on a backside isolation structure, according to one or more embodiments.

FIGS. 7A-7C illustrate a semiconductor device in a forksheet transistor structure in which BJTs are formed on a backside isolation structure, according to one or more embodiments.

FIG. 8 illustrates a semiconductor device in a stacked forksheet transistor structure in which stacked forksheet transistors, passive devices and BJTs are formed on a backside isolation structure, according to one or more embodiments.

FIGS. 9A through 9I illustrate cross-section views of intermediate semiconductor devices after respective steps of manufacturing a semiconductor device in a forksheet transistor structure in which passive devices are formed on a backside isolation structure, according to one or more embodiments.

FIGS. 10A and 10B illustrate a flowchart of a method of manufacturing a semiconductor device in a forksheet transistor structure including a passive device or a BJT on a backside isolation structure, according to one or more embodiments.

FIG. 11 illustrates a semiconductor device in a forksheet transistor structure in which a passive device is formed on a substrate, according to one or more embodiments.

FIG. 12 illustrates a semiconductor device in a forksheet transistor structure in which a BJT is formed on a substrate, according to one or more embodiments.

FIG. 13 illustrates a semiconductor device in a stacked forksheet transistor structure in which a passive device is formed on a substrate, according to one or more embodiments.

FIG. 14. is a schematic block diagram illustrating an electronic device including a semiconductor device in a forksheet transistor structure in which at least one of a passive device and a BJT is formed, according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element may be a “right” element and a “left” element when a device or structure including these elements are differently oriented.

It will be understood that, although the terms “1^{st},” “2^{nd},” “3^{rd},” “4^{th},” “5^{th},” “6^{th},” etc. may be used herein to describe various elements, these elements should not be limited by these terms. These terms are only used to distinguish one element from another element. Thus, a 1^{st} element described in the descriptions of an embodiments could be termed a 2^{nd} element in the descriptions of another element or one or more claims, and vice versa without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c.

Herein, the terms of degree including “substantially” or “about” may be used. In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X. Still, when a term “same” is used to compare parameters of two or more elements, the term may cover “substantially same” parameters.

It will be understood that, when the term “contact” is used to describe two metal elements, for example, a metal line and a via structure, a barrier metal layer such as titanium (Ti), tantalum (Ta), titanium nitride (TiN), tantalum nitride (TaN), tungsten nitride (WN), nickel nitride (NiN), cobalt nitride (CoN), or platinum nitride (PtN), not being limited thereto, may be formed therebetween. Further, it will be understood that, when a metal contact structure is described as being formed on or contact a surface of a source/drain pattern, a silicide layer such as cobalt silicide (CoSi₂), nickel silicide (NiSi₂), titanium silicide (TiSi₂), or tungsten silicide (WSi₂), not being limited thereto, may be formed therebetween.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments. Herein, the term “isolation” pertains to electrical insulation or separation between structures, layers, components or regions in a corresponding device or structure.

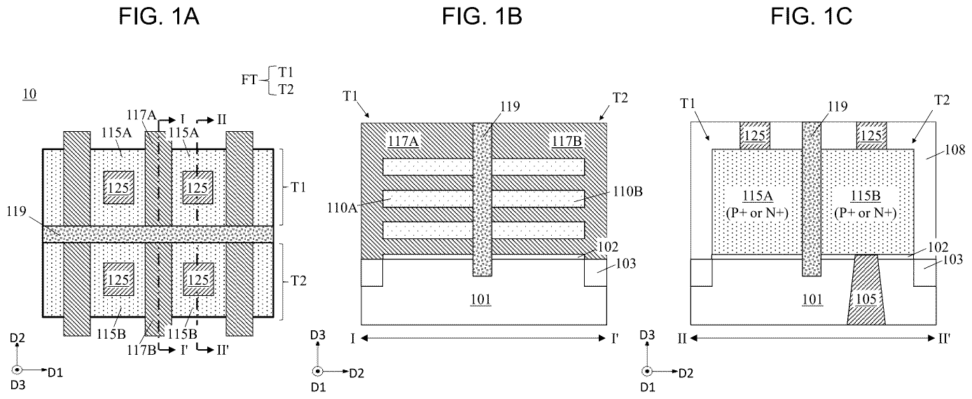

FIGS. 1A-1C illustrate a semiconductor device including a forksheet transistor in which a BSPDN structure is formed, according to one or more embodiments.

FIG. 1A is a plan view of a semiconductor device 10, FIG. 1B is a cross-section view of the semiconductor device 10 shown in FIG. 1A taken along lines I-I′, and FIG. 1C is a cross-section view of the semiconductor device 10 shown in FIG. 1A taken along lines II-II′. It is to be understood here that FIG. 1A is provided to show a positional relationship between selected structural elements of the semiconductor device 10, and thus, some structural elements such as an isolation structure may not be shown in FIG. 1A.

As shown in FIGS. 1A-1C, a D1 direction is a channel-length direction in which a current flows between two source/drain patterns (or source/drain regions) connected to each other through a channel structure, a D2 direction is a channel-width direction that intersects the D1 direction, and a D3 direction is a vertical direction that intersects the D1 and D2 directions both of which are horizontal directions.

Referring to FIGS. 1A-1C, the semiconductor device 10 may include a forksheet transistor FT formed of a 1^{st} nanosheet transistor T1 and a 2^{nd} nanosheet transistor T2 isolated from each other by an isolation wall 119 extending along the D1 direction.

The 1^{st} nanosheet transistor T1 may include a plurality of 1^{st} channel layers 110A as a channel structure on a backside isolation structure 101, a 1^{st} gate structure 117A extending along the D2 direction and surrounding the 1^{st} channel layers 110A, and 1^{st} source/drain patterns 115A formed on the 1^{st} channel layers 110A at both sides thereof along the D1 direction. The 1^{st} source/drain patterns 115A may be epitaxially grown from the 1^{st} channel layers 110A in a process of manufacturing the semiconductor device 10.

Similarly, the 2^{nd} nanosheet transistor T2 may include 2^{nd} channels layers 110B as a channel structure on the backside isolation structure 101, a 2^{nd} gate structure 117B extending along the D2 direction and surrounding the 2^{nd} channel layers 110B, and 2^{nd} source/drain patterns 115B formed on the 2^{nd} channel layers 110B at both sides thereof along the D1 direction. The 2^{nd} source/drain patterns 115B may be epitaxially grown from the 2^{nd} channel layers 110B in the process of manufacturing the semiconductor device 10.

The channel layers 110A and 110B may be referred to as nanosheet layers epitaxially grown from the substrate that is replaced by the backside isolation structure 101 in the process of manufacturing the semiconductor device 10. Like the substrate, the channel layers 110A and 110B may be formed of silicon (Si).

The 1^{st} source/drain patterns 115A may be formed of or include Si or silicon germanium (SiGe), and may be doped in-situ with n-type impurities (e.g., phosphorus, arsenic, antimony, etc.) or p-type impurities (e.g., boron, gallium, indium, etc.) to form the 1^{st} nanosheet transistor T1 as n-type field-effect transistor (NFET) or p-type field-effect transistor (PFET). The 2^{nd} source/drain patterns 115B may also be formed of or include Si or SiGe, and may be doped in-situ with n-type impurities or p-type impurities to form the 2^{nd} nanosheet transistor T2 as NFET or PFET. Thus, in a case where the 1^{st} nanosheet transistor is formed as NFET, the 2^{nd} nanosheet transistor may be formed as NFET or PFET, and in a case where the 1^{st} nanosheet transistor is formed as PFET, the 2^{nd} nanosheet transistor may be formed as PFET or NFET.

Each of the gate structures 117A and 117B may include a gate dielectric layer, a work-function metal layer, and a gate electrode. The gate dielectric layer may include an interfacial layer formed of an oxide material such as silicon oxide (SiO₂) and/or SiON, not being limited thereto. The gate dielectric layer may further include a high-k layer formed of a high-k material such as Hf, Al, Zr, La, Mg, Ba, Ti, Pb, and/or a composite thereof, not being limited thereto. The work-function metal layer may be formed of a metal such as Ti, Ta, TiN, WN, TiAl, TiAlN, TaN, TiC, TaC, TiAlC, TaCN, TaSiN, and/or a composite thereof, not being limited thereto. However, the work-function metal layers of the gate structures 117A and 117B may be different in the case where the 1^{st} nanosheet transistor T1 is an NFET and the 2^{nd} nanosheet transistor T2 is a PFET so that they may have different gate threshold voltages. The gate electrode of each of the gate structures 117A and 117B may be formed of Cu, W, Al, Ru, Mo, Co, and/or a composite thereof, not being limited thereto.

The semiconductor device 10 may include a plurality of other gate structures extending in the D2 direction at a left side and a right side of the 1^{st} gate structure 117A and the 2^{nd} gate structure 117B along the D1 direction. These gate structures including the gate structures 117A and 117B may be spaced apart by a predetermined gate pitch in the D1 direction.

The isolation wall 119 may electrically isolate the 1^{st} nanosheet transistor T1 and the 2^{nd} nanosheet transistor T2 from each other. For example, the isolation wall 119 may isolate the 1^{st} channel layers 110A from the 2^{nd} channel layers 110B, and may also isolate the 1^{st} source/drain pattern 115A from the 2^{nd} source/drain pattern 115B. The isolation wall 119 may also be formed such that a right side surface of each of the 1^{st} channel layers 110A contacts a left side surface of the isolation wall 119, and a left side surface of each of the 2^{nd} channel layers 110B contacts a right side surface of the isolation wall 119 as shown in FIG. 1B. Accordingly, a right side surface of the 1^{st} source/drain pattern 115A may contact the left side surface of the isolation wall 119, and a left side surface of the 2^{nd} source/drain pattern 115B may contact the right side surface of the isolation wall 119 as shown in FIG. 1B. Further, the isolation wall 119 may isolate the 1^{st} gate structure 117A from the 2^{nd} gate structure 117B as shown in FIGS. 1A and 1B.

The isolation wall 119 may be formed of a dielectric material such as silicon nitride (Si₃N₄), silicon oxide (e.g., SiO₂), silicon oxynitride (SiON), etc., not being limited thereto, to serve as a dielectric barrier between the two nanosheet transistors T1 and T2 formed in parallel. For example, the 1^{st} nanosheet transistor T1 may be an NFET and the 2^{nd} nanosheet transistor T2 may be a PFET. Due to this isolation wall 119, the two opposite-polarity nanosheet transistors T1 and T2 may be formed to be closer in the D2 direction without causing capacitance-related issues, which would otherwise impact performance and power consumption of the semiconductor device 10. Further, the isolation wall 119 may enable the semiconductor device 10 to achieve an additional area gain without a short-circuit risk between the two parallel nanosheet transistors T1 and T2. However, the disclosure is not limited thereto. The two nanosheet transistors T1 and T2 may each be of a same type, that is, a PFET or an NFET.

The backside isolation structure 101 may be formed of a low-k dielectric material such as silicon oxide (SiO₂), not being limited thereto. The backside isolation structure 101 may be formed by replacing a silicon-based substrate from which the channel layers 110A and 110B are epitaxially grown. The backside isolation structure 101 will be further described later.

On an upper-left corner and an upper-right corner of the backside isolation structure 101 may be formed a shallow trench isolation (STI) structure 103 extending in the D1 direction. The STI structure 103 may be formed to isolate an active region of the substrate to be replaced by the backside isolation structure 101 for the forksheet transistor FT from an active region of the substrate for an adjacent forksheet transistor. The STI structure 103 may include silicon oxide (SiO₂), not being limited thereto. Further, a bottom dielectric isolation layer 102 may be formed on a bottom surface of each of the source/drain patterns 115A, 115B and the gate structures 117A, 117B to prevent current leakage from these active patterns into the backside isolation structure 101. The bottom dielectric isolation layer 102 may include a material such as silicon nitride (Si₃N₄), etc., not being limited thereto.

The source/drain patterns 115A and 115B may be surrounded by, or isolated from each other and other circuit elements through an interlayer dielectric (ILD) layer 108 which may be formed of a low-k dielectric material such as silicon oxide (e.g., SiO₂), silicon nitride (Si₃N₄), SiON, etc., not being limited thereto.

On top surfaces of the source/drain patterns 115A and 115B may be formed frontside contact plugs 125, respectively, at least one of which is connected to a voltage source or another circuit element for signal routing. Moreover, a backside contact plug 105 may be formed on the bottom surface of the 2^{nd} source/drain pattern 115B inside the backside isolation structure 101 to connect the 2^{nd} source/drain pattern 115B to a voltage source or another circuit element. The backside isolation structure 101 and the backside contact plug 105 may form a BSPDN structure of the semiconductor device 10. The frontside contact plugs 125 and the backside contact plug 105 may each be formed of one or more conductive materials such as Cu, W, Al, Ru, Mo, Co, and/or a compound thereof, not being limited thereto. Although FIG. 1A shows that all of the source/drain patterns 115A and 115B have respective frontside contact plugs 125 thereon, one or more of these contact structures may not be formed depending on a circuit design. Similarly, although FIG. 1C shows only one backside contact plug 105 on the bottom surface of the source/drain pattern 115B, the backside contact plug 105 may be formed on a bottom surface of one or more other source/drain patterns whether or not they are connected to a voltage source or other circuit elements subject to a circuit design.

In the meantime, as described above, the backside isolation structure 101 of a low-k dielectric material such as silicon oxide (SiO₂) may be formed by replacing a substrate which may include a group IV semiconductor (e.g., Si), a group III-V compound semiconductor, or a group II-VI compound semiconductor, not being limited thereto. Thus, a passive device such as a PN diode or a bipolar junction transistor (BJT) that can be formed in or inside the substrate may not be formed in the backside isolation structure 101 in the semiconductor device 10. Thus, a separate substrate may need to be formed in the semiconductor device 10 to form a passive device or a BJT therein, which may increase the footprint of the semiconductor device 10 and render a manufacturing process complicated. Thus, various embodiments described herebelow address this problem of forming a passive device and a BJT in a semiconductor device in a forksheet transistor structure including a backside isolation structure.

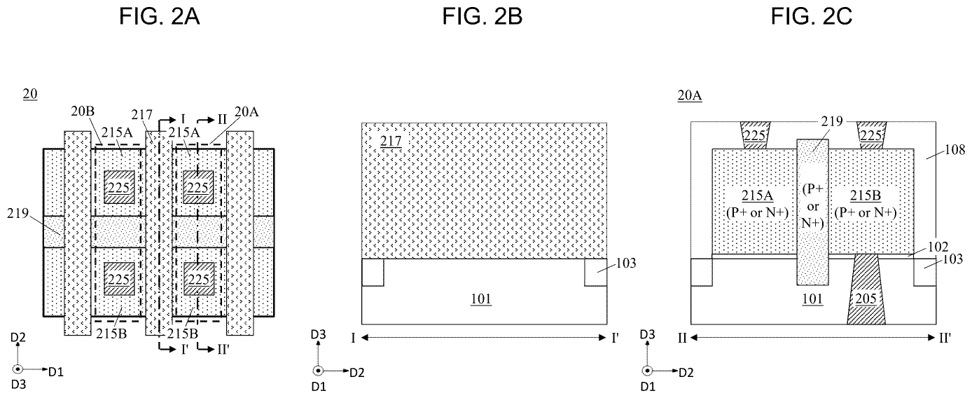

FIGS. 2A-2C illustrate a semiconductor device in a forksheet transistor structure in which passive devices are formed on a backside isolation structure, according to one or more embodiments.

FIG. 2A is a plan view of a semiconductor device 20, FIG. 2B is a cross-section view of the semiconductor device 20 shown in FIG. 2A taken along lines I-I′, and FIG. 2C is a cross-section view of the semiconductor device 20 shown in FIG. 2A taken along lines II-II′. It is to be understood here that FIG. 2A is provided to show a positional relationship between selected structural elements of the semiconductor device 20, and thus, some structural elements such as an isolation structure may not be shown in FIG. 2A.

Referring to FIGS. 2A-2C, the semiconductor device 20 may include a plurality of passive devices, for example, a 1^{st} PN diode 20A and a 2^{nd} PN diode 20B, on or above the backside isolation structure 101, which may be an extension of the backside isolation structure 101 of the semiconductor device 10 of FIGS. 1A-1C.

As will be described below in detail, the semiconductor device 20 is characterized in that the 1^{st} PN diode 20A and the 2^{nd} PN diode 20B may be formed using a forksheet transistor structure formed on the backside isolation structures 101. For example, as the backside isolation structure 101 of a low-k dielectric material such as silicon oxide does not allow formation of the PN diodes 20A and 20B therein, these passive devices may be formed of 1^{st} semiconductor layers 215A, 2^{nd} semiconductor layers 215B, and a semiconductor wall 219 that are disposed at a position of the forksheet transistor FT formed of the nanosheet transistors T1 and T2 in the semiconductor device 10. The semiconductor layers 215A and 215B may be epitaxial structures of silicon (Si) or silicon germanium (SiGe) grown to form source/drain patterns of a forksheet transistor, and the semiconductor wall 219 may be an epitaxial structure of silicon (Si) that has replaced an isolation wall of a dielectric material formed to isolate two nanosheet transistors of the forksheet transistor.

Like the source/drain patterns 115A and 115B of the semiconductor device 10 of FIGS. 1A-1C, the 1^{st} semiconductor layers 215A and the 2^{nd} semiconductor layers 215B may be epitaxially grown from channel layers corresponding to the channel layers 110A and 110B of the semiconductor device 10, and also, may be in-situ doped with p-type impurities or n-type impurities according to a circuit design for the semiconductor device 20. The semiconductor wall 219 may be formed at a position of the isolation wall 119 of the semiconductor device 10. The semiconductor wall 219 may be epitaxially grown from the substrate, which is replaced by the backside isolation structure 101, and may also be in-situ doped with p-type impurities or n-type impurities in a process of manufacturing the semiconductor device 20.

Further, in the semiconductor device 20, diffusion break structures 217 may be formed by replacing respective gate structures and channel layers surrounded by the gate structures, which are formed in the process of manufacturing the semiconductor device 20. Unlike the gate structures in the semiconductor device 10 divided by the isolation wall 119 along the D2 direction, the diffusion break structures 217 may divide the semiconductor wall 219 in the D1 direction so that the 1^{st} PN diode 20A and the 2^{nd} PN diode 20B can be isolated from each other though the diffusion break structure 217 therebetween in the D1 direction.

For example, in a case where the 1^{st} semiconductor layer 215A is of p-type to form an anode, the 2^{nd} semiconductor layer 215B at an opposite side of the 1^{st} semiconductor layer 215A with respect to the semiconductor wall 219 in the D2 direction may be of n-type to form a cathode. At this time, the semiconductor wall 219 may be formed as either p-type or n-type. As another example, in a case where the 1^{st} semiconductor layer 215A is of n-type to form a cathode, the 2^{nd} semiconductor layer 215B may be of p-type to form an anode. At this time, the semiconductor wall 219 may be formed as either n-type or p-type. For either of the semiconductor layers 215A and 215B to be formed as n-type, the semiconductor layer may be formed of Si with n-type impurities therein. For either of the semiconductor layers 215A and 215B to be formed as p-type, the semiconductor layer may be formed of SiGe with p-type impurities therein.

Like the semiconductor device 10, the semiconductor device 20 may include frontside contact plugs 225 formed on the semiconductor layers 215A and 215B, respectively. Additionally or alternatively, a backside contact plug 205 may be formed on at least one of the semiconductor layers 215A and 215B. For example, the backside contact plug 205 and the frontside contact plug 225 may be formed on a bottom surface and a top surface of the 2^{nd} semiconductor layer 215B, respectively, as shown in FIG. 2C. In this case, one of the two contact plugs 205 and 225 for the 2^{nd} semiconductor layer 215B may be disabled, for example, by not being connected to a voltage source or any other circuit element. The contact plugs 205 and 225 may function as anode contacts and cathode contacts connecting the semiconductor layers 215A and 215B to respective voltage sources opposite to each other.

Thus, even if a backside isolation structure is formed to provide a space for forming a BSPDN structure for one or more forksheet transistors, PN diodes may be formed based on semiconductor layers grown to form source/drain patterns of the forksheet transistors and a semiconductor wall that replaces an isolation wall formed for the forksheet transistors.

In the meantime, the semiconductor wall 219 in the semiconductor device 20 may be formed to have a greater width than the isolation wall 119 of the semiconductor device 10 to secure a sufficient depletion region for the PN diodes 20A and 20B, according to one or more embodiments.

In the above embodiments, passive devices such as PN diodes are formed based on a forksheet transistor structure. However, the disclosure is not limited thereto. In the embodiments described below, a forksheet transistor structure may also be used to form BJT devices.

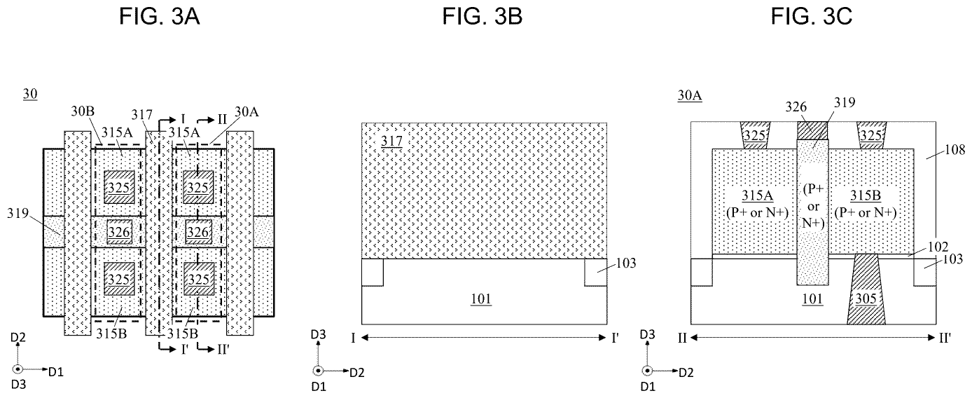

FIGS. 3A-3C illustrate a semiconductor device in a forksheet transistor structure in which BJTs are formed on a backside isolation structure, according to one or more embodiments.

FIG. 3A is a plan view of a semiconductor device 30, FIG. 3B is a cross-section view of the semiconductor device 30 shown in FIG. 3A taken along lines I-I′, and FIG. 3C is a cross-section view of the semiconductor device 30 shown in FIG. 3A taken along lines II-II′. It is to be understood here that FIG. 3A is provided to show a positional relationship between selected structural elements of the semiconductor device 30, and thus, some structural elements such as an isolation structure may not be shown in FIG. 3A.

Referring to FIGS. 3A-3C, the semiconductor device 30 may include a plurality of BJTs, for example, a 1^{st} BJT 30A and a 2^{nd} BJT 30B, on or above the backside isolation structure 101, which may be an extension of the backside isolation structure 101 of the semiconductor devices 10 and 20 shown in FIGS. 1A-1C and FIGS. 2A-2C.

Like the semiconductor device 20, the semiconductor device 30 may also be formed based on a forksheet transistor structure, and, each of the 1^{st} BJT 30A and the 2^{nd} BJT 30B may include a 1^{st} semiconductor layer 315A, a semiconductor wall 319, and a 2^{nd} semiconductor layer 315B on the same backside isolation structure 101. Similar to the semiconductor layers 215A and 215B of the semiconductor device 20, the semiconductor layers 315A and 315B may also be epitaxial structures of silicon (Si) or silicon germanium (SiGe) grown to form source/drain patterns of a forksheet transistor. The semiconductor wall 319 forming the semiconductor device 30 may be an epitaxial structure of silicon (Si) that has replaced an isolation wall of a dielectric material formed to isolate two nanosheet transistors of each of the forksheet transistor. The semiconductor wall 319 may be an extension of the semiconductor wall 219 according to one or more embodiments.

The 1^{st} semiconductor layers 315A and the 2^{nd} semiconductor layers 315B may be epitaxially grown from channel layers corresponding to the channel layers 110A and 110B of the semiconductor device 10, and also, may be in-situ doped with p-type impurities or n-type impurities according to a circuit design for the semiconductor device 30. However, unlike the semiconductor layers 215A and 215B of the semiconductor device 20 having opposite polarities, both of the semiconductor layers 315A and 315B may be formed as p-type regions or n-type regions while the semiconductor wall 319 may be formed as an opposite-type region to form a PNP or NPN BJT. Like the semiconductor wall 219, the semiconductor wall 319 may also be epitaxially grown from a substrate, which is replaced by the backside isolation structure 101, and may also be in-situ doped with p-type impurities or n-type impurities in a process of manufacturing the semiconductor device 30.

For example, in a case where both of the semiconductor layers 315A and 315B are of p-type, the semiconductor wall 319 may be of n-type so that the semiconductor layers 315A, 315B and the semiconductor wall 319 can form an emitter, a collector and a sof a PNP BJT, respectively. As another example, in a case where both of the semiconductor layers 315A and 315B are of n-type, the semiconductor wall 319 may be of p-type so that the semiconductor layers 315A, 315B and the semiconductor wall 319 can form an emitter, a collector, and a base of an NPN BJT, respectively. As in the PN diode 20A, for either of the semiconductor layers 315A and 315B to be formed as n-type, the semiconductor layer may be formed of Si with n-type impurities. For either of the semiconductor layers 315A and 315B to be formed as p-type, the semiconductor layer may be formed of SiGe with p-type impurities.

The BJTs 30A an 30B may also include frontside contact plugs 325 formed on the semiconductor layers 315A and 315B, respectively. Further, another frontside contact plug 326 may be formed on the semiconductor wall 319. Additionally or alternatively, a backside contact plug 305 may be formed on at least one of the semiconductor layers 315A, 315B and the semiconductor wall 319. For example, the backside contact plug 305 and the frontside contact plug 325 may be formed on the bottom surface and the top surface of the 2^{nd} semiconductor layer 315B, respectively, as shown in FIG. 3C. In this case, one of the two contact plugs 305 and 325 may be disabled, for example, by not being connected to a voltage source or any other circuit element. The contact plugs 305, 325 and 326 may function as emitter contacts, a base contact, and collector contacts, respectively.

Thus, even if a backside isolation structure is formed to provide a space for forming a BSPDN structure for one or more forksheet transistors, BJTs may be formed based on semiconductor layers grown to form source/drain patterns of the forksheet transistors and a semiconductor wall that replaces an isolation wall formed for the forksheet transistors.

In the meantime, in the semiconductor device 30, one of the two devices 30A and 30B may be formed as a PN diode by controlling polarities of the semiconductor layers 315A and 315B while the other of the two devices 30A and 30B is formed a BJT as described above. For example, in a case where the semiconductor wall 319 is formed as n-type and the semiconductor layers 315A and 315B of the device 30A are formed as p-type to form a PNP BJT, the semiconductor layers 315A and 315B of the device 30B may be formed as p-type and n-type, respectively, and the frontside contact plug 326 on the semiconductor wall 319 between these two semiconductor layers 315A and 315B may be disabled. Thus, the semiconductor device 30 may be formed as a combination of a BJT 30A and a PN diode 30B based on a forksheet transistor structure.

In the above embodiments, the semiconductor wall 319 is described as being formed of silicon (Si) doped with p-type impurities or n-type impurities. However, the semiconductor wall 319 may be formed of silicon-germanium (SiGe) doped with p-type impurities, while each of the semiconductor layers 315A and 315B may be formed of silicon (Si) doped with n-type impurities. This configuration allows at least one of the BJTs 30A and 30B to function as a heterojunction bipolar transistor (HBT), enabling high-speed carrier transport and improved performance at high frequencies.

As described above in reference to FIGS. 2A-2C and 3A-3C, the forksheet transistor structure formed on a backside isolation structure is used to form PN diodes and BJTs. However, the forksheet transistor structure is provided to form forksheet transistors including the forksheet transistor FT shown in FIGS. 1A-1C according to the original circuit design. Thus, a semiconductor device based on a forksheet transistor structure may be formed to include at least two of the semiconductor devices 10, 20, 30 and the variant of the semiconductor device 30 including a combination of a BJT and a PN diode as described above. This semiconductor device may also include the same backside isolation structure 101, the same STI structure 103, the same bottom dielectric isolation layer 102, and the same ILD layer 108, as shown in FIGS. 1A-1C, 2A-2C and 3A-3C.

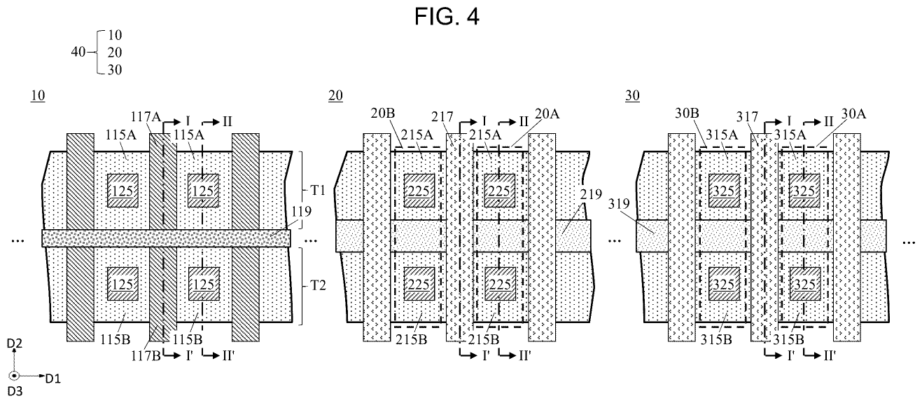

FIG. 4 illustrates a semiconductor device in a forksheet transistor structure in which a forksheet transistor, passive devices and BJTs are formed on a backside isolation structure, according to one or more embodiments.

Referring to FIG. 4, a semiconductor device 40 may include the semiconductor device 10 of FIGS. 1A-1C, the semiconductor device 20 of FIGS. 2A-2C, and the semiconductor device 30 of FIGS. 3A-3C formed on a same backside isolation structure which has replaced a same substrate.

As described above, source/drain patterns epitaxially grown from the channel layers to form a forksheet transistor, corresponding to the channel layers 110A and 110B of the forksheet transistor FT of the semiconductor device 10, may form the semiconductor layers 215A and 215B of the semiconductor device 20 and the semiconductor layers 315A and 315B of the semiconductor device 30. Thus, the semiconductor layers 215A and 215B, the semiconductor layers 315A and 315B, and the source/drain patterns 115A and 115B may have the same or substantially same sizes, respectively. For example, these epitaxial structures may have the same or substantially same height, width and length.

As the semiconductor devices 10, 20 and 30 including the forksheet transistors FT, the PN diodes 20A, 20B and the BJTs 30A, 30B can be formed based on the same substrate, separate formation of the passive devices and the BJTs using one or more different substrates may be avoided to achieve a device density and manufacturing efficiency.

FIG. 4 shows that the semiconductor devices 10-30 are arranged in the D1 direction. However, the disclosure is not limited there to. According to one or more other embodiments, the semiconductor devices 10-30 may be arranged in the D2 direction or may be formed at different positions to form the semiconductor device 40 in a forksheet transistor structure in which one or more forksheet transistors, one or more PN diodes and one or more BJTs are formed. Moreover, the variants of the semiconductor device 30 discussed above in reference to FIGS. 3A-3C may also be included in the semiconductor device 40.

Utilizing the forksheet transistor structure to form PN diodes and BJTs may also apply to a semiconductor device which has been introduced in a response to increased demand for an integrated circuit having a high device density and performance. This semiconductor device may include a 1^{st} transistor at a 1^{st} level and a 2^{nd} transistor at a 2^{nd} level above the 1^{st} level, where each of the two transistors may be a field-effect transistor such as FinFET, nanosheet transistor, forksheet transistor, or any other type of FET.

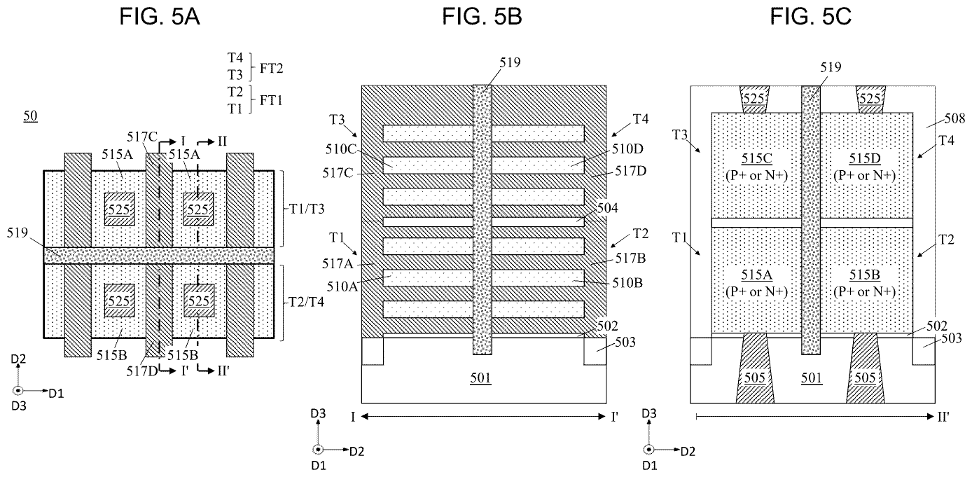

FIGS. 5A-5C illustrate a semiconductor device in a forksheet transistor structure in which passive devices are formed on a backside isolation structure, according to one or more embodiments.

FIG. 5A is a plan view of a semiconductor device 50, FIG. 5B is a cross-section view of the semiconductor device 50 shown in FIG. 5A taken along lines I-I′, and FIG. 5C is a cross-section view of the semiconductor device 50 shown in FIG. 5A taken along lines II-II′. It is to be understood here that FIG. 5A is provided to show a positional relationship between selected structural elements of the semiconductor device 50, and thus, some structural elements such as an isolation structure may not be shown in FIG. 5A.

Referring to FIGS. 5A-5C, the semiconductor device 50 may include a 1^{st} forksheet transistor FT1 at a 1^{st} level and a 2^{nd} forksheet transistor FT2 at a 2^{nd} level above the 1^{st} level in the D3 direction. The 1^{st} forksheet transistor FT1 may be formed of a 1^{st} nanosheet transistor T1 and a 2^{nd} nanosheet transistor T2 isolated from each other by an isolation wall 519 extending along the D1 direction. The 1^{st} forksheet transistor FT2 may be formed of a 3^{rd} nanosheet transistor T3 and a 4^{th} nanosheet transistor T4 isolated from each other by the isolation wall 519.

The 1^{st} nanosheet transistor T1 may include a plurality of 1^{st} channel layers 510A as channel structure on a backside isolation structure 501, a 1^{st} gate structure 517A, and 1^{st} source/drain patterns 515A. The 2^{nd} nanosheet transistor T2 may include a plurality of 2^{nd} channel layers 510B as a channel structure on the backside isolation structure 501, a 2^{nd} gate structure 517B, and 2^{nd} source/drain patterns 515B. The 3^{rd} nanosheet transistor T3 above the 1^{st} nanosheet transistor T1 may include a plurality of 3^{rd} channel layers 510C as a channel structure, a 3^{rd} gate structure 517C, and 3^{rd} source/drain patterns 515C. The 4^{th} nanosheet transistor T4 above the 2^{nd} nanosheet transistor T2 may include a plurality of 4^{th} channel layers 510D as a channel structure, a 4^{th} gate structure 517D, and 4^{th} source/drain patterns 515D.

The forksheet transistor FT1 of the semiconductor device 50 may be the same as the forksheet transistor FT of the semiconductor device 10 shown in FIGS. 1A-1C in terms of their structures and constituent materials. Further, in the semiconductor device 50, the forksheet transistor FT2 may be the same as the forksheet transistor FT1 in the semiconductor device 50 in terms of their structures and constituent materials. However, the nanosheet transistors T1-T4 forming the forksheet transistors FT1 and FT2 may have the same or different polarities.

The backside isolation structure 501, a bottom dielectric isolation layer 502, an STI structure 503, an ILD layer 508, and the isolation wall 519 may be the same as the backside isolation structure 101, the bottom dielectric isolation layer 102, the STI structure 103, the ILD layer 108, and the isolation wall 119 of the semiconductor device 10 of FIGS. 1A-1C, respectively, in terms of their structures and constituent materials. Thus, duplicate descriptions thereof may be omitted herein.

On top surfaces of the source/drain patterns 515C and 515D may be formed frontside contact plugs 525, respectively, connected to voltage sources or other circuit elements for signal routing, respectively. Moreover, backside contact plugs 505 may be formed on bottom surfaces of the source/drain patterns 515A and 515B inside the backside isolation structure 501 to connect these source/drain patterns to voltage sources or other circuit elements, respectively. The backside isolation structure 501 and the backside contact plugs 505 may form a BSPDN structure of the semiconductor device 50. The contact plugs 505 and 525 may each be formed of one or more conductive materials such as Cu, W, Al, Ru, Mo, Co, and/or a compound thereof, not being limited thereto.

Similar to the semiconductor device 10 of FIGS. 1A-1C, the semiconductor device 50 may not allow formation of a passive device such as a PN diode or a BJT that can be formed in or inside a substrate because the backside isolation structure 501 may have replaced the substrate. Thus, the following embodiments provide a semiconductor device including a passive device and a BJT formed based on a stacked forksheet transistor structure including a BSPDN structure.

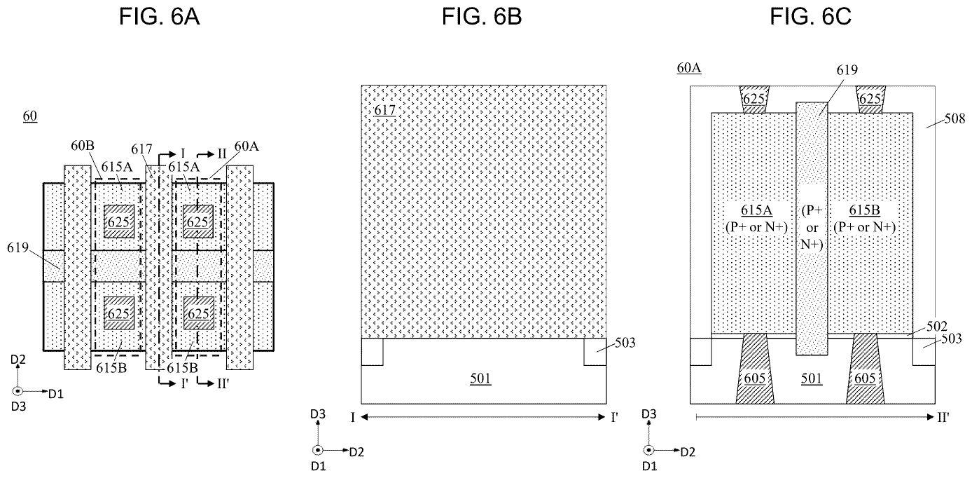

FIGS. 6A-6C illustrate a semiconductor device in a stacked forksheet transistor structure in which passive devices are formed on a backside isolation structure, according to one or more embodiments.

FIG. 6A is a plan view of a semiconductor device 60, FIG. 6B is a cross-section view of the semiconductor device 60 shown in FIG. 6A taken along lines I-I′, and FIG. 6C is a cross-section view of the semiconductor device 60 shown in FIG. 6A taken along lines II-II′. It is to be understood here that FIG. 6A is provided to show a positional relationship between selected structural elements of the semiconductor device 60, and thus, some structural elements such as an isolation structure may not be shown in FIG. 6A.

Referring to FIGS. 6A-6C, the semiconductor device 60 may include a plurality of passive devices, for example, a 1^{st} PN diode 60A and a 2^{nd} PN diode 60B, on or above the backside isolation structure 501, which may be the same as or an extension of the backside isolation structure 501 of the semiconductor device 50 shown in FIGS. 5A-5C.

Similar to the semiconductor device 20 of FIGS. 2A-2C, the semiconductor device 60 is characterized in that the 1^{st} PN diode 60A and the 2^{nd} PN diode 60B may be formed using a forksheet transistor structure formed on the backside isolation structures 501. For example, as the backside isolation structure 501 of a low-k dielectric material such as silicon oxide does not allow formation of the PN diodes 60A and 60B therein, these passive devices may be formed of 1^{st} semiconductor layers 615A, 2^{nd} semiconductor layers 615B, and a semiconductor wall 619 that are disposed at a position of the stacked forksheet transistors FT1 and FT2 formed of the nanosheet transistors T1-T4 in the semiconductor device 50.

Also, similar to the semiconductor layers 215A and 215B of the semiconductor device 20 of FIGS. 2A-2C, the semiconductor layers 615A and 615B may also be epitaxial structures of silicon (Si) or silicon germanium (SiGe) grown to form source/drain patterns of forksheet transistors, and the semiconductor wall 619 may be an epitaxial structure of silicon (Si) that has replaced an isolation wall of a dielectric material formed to isolate two nanosheet transistors of each of a 1^{st}-level forksheet transistor and a 2^{nd}-level forksheet transistor corresponding to the 1^{st} forksheet transistor FT1 and the 2^{nd} forksheet transistor FT2 of the semiconductor device 50, respectively.

Further, the semiconductor layers 615A, 615B and the semiconductor wall 619 may be formed of the same materials forming the semiconductor layers 215A, 215B and the semiconductor wall 219 of the semiconductor device 20, respectively, and may be polarized in the same manner as the semiconductor layers 215A, 215B and the semiconductor wall 219 are polarized. For example, in a case where the 1^{st} semiconductor layer 615A is of p-type to form an anode, the 2^{nd} semiconductor layer 615B at an opposite side of the 1^{st} semiconductor layer 615A with respect to the semiconductor wall 619 in the D2 direction may be of n-type to form a cathode. At this time, the semiconductor wall 619 may be formed as either p-type or n-type. As another example, in a case where the 1^{st} semiconductor layer 615A is of n-type to form a cathode, the 2^{nd} semiconductor layer 615B may be of p-type to form an anode. At this time, the semiconductor wall 619 may be formed as either n-type or p-type. For either of the semiconductor layers 615A and 615B to be formed as n-type, the semiconductor layer may be formed of Si with n-type impurities therein. For either of the semiconductor layers 615A and 615B to be formed as p-type, the semiconductor layer may be formed of SiGe with p-type impurities therein.

However, unlike each of the semiconductor layers 215A and 215B which is grown from channel layers for one nanosheet transistor, each of the semiconductor layers 615A and 615B may be grown from channel layers for two nanosheet transistors at the 1^{st} level and the 2^{nd} level. For example, the 1^{st} semiconductor layer 615A may be grown from channel layers corresponding to the 1^{st} channel layers 510A of the 1^{st} nanosheet transistor T1 and the 3^{rd} channel layers 510C of the 3^{rd} nanosheet transistor T3, and the 2^{nd} semiconductor layer 615B may be grown from channel layers corresponding to the 2^{nd} channel layers 510B of the 2^{nd} nanosheet transistor T2 and the 4^{th} channel layers 510D of the 4^{th} nanosheet transistor T4. Thus, the PN diodes 60A and 60B of the semiconductor device 60 may have a larger size in each of the p-type region and the n-type region to improve the device performance, compared to the PN diodes 20A and 20B of the semiconductor device 20.

In addition, in the semiconductor device 60, diffusion break structures 617 may be formed by replacing respective gate structures and channel layers surrounded by the gate structures, which are formed in the process of manufacturing the semiconductor device 60. Unlike the gate structures in the semiconductor device 50 divided by the isolation wall 519 along the D2 direction, the diffusion break structures 617 may divide the semiconductor wall 619 in the D1 direction so that the 1^{st} PN diode 60A and the 2^{nd} PN diode 60B can be isolated from each other though the diffusion break structure 617 therebetween in the D1 direction.

Like the semiconductor device 50, the semiconductor device 60 may include frontside contact plugs 625 formed on the semiconductor layers 615A and 615B, respectively. Additionally or alternatively, backside contact plugs 605 may be formed on the semiconductor layers 615A and 615B. For example, the backside contact plug 605 and the frontside contact plug 625 may be formed on a bottom surface and a top surface of each of the semiconductor layers 615A and 615B, respectively, as shown in FIG. 6C. In this case, one of the two contact plugs 605 and 625 for the 2^{nd} semiconductor layer 615B may be disabled, for example, by not being connected to a voltage source or any other circuit element. The contact plugs 605 and 625 may function as anode contacts and cathode contacts connecting the semiconductor layers 615A and 615B to respective voltage sources opposite to each other.

Thus, even if a backside isolation structure is formed to provide a space for forming a BSPDN structure for stacked forksheet transistors, PN diodes may be formed based on semiconductor layers grown to form source/drain patterns for the stacked forksheet transistors and a semiconductor wall that replaces an isolation wall formed for the stacked forksheet transistors.

In the meantime, the semiconductor wall 619 in the semiconductor device 60 may be formed to have a greater width than the isolation wall 519 of the semiconductor device 50 to secure a sufficient depletion region for the PN diodes 60A and 60B, according to one or more embodiments.

In the above embodiments, passive devices such as PN diodes are formed based on a stacked forksheet transistor structure. However, the disclosure is not limited thereto. In the embodiments described below, the stacked forksheet transistor structure may also be used to form BJT devices.

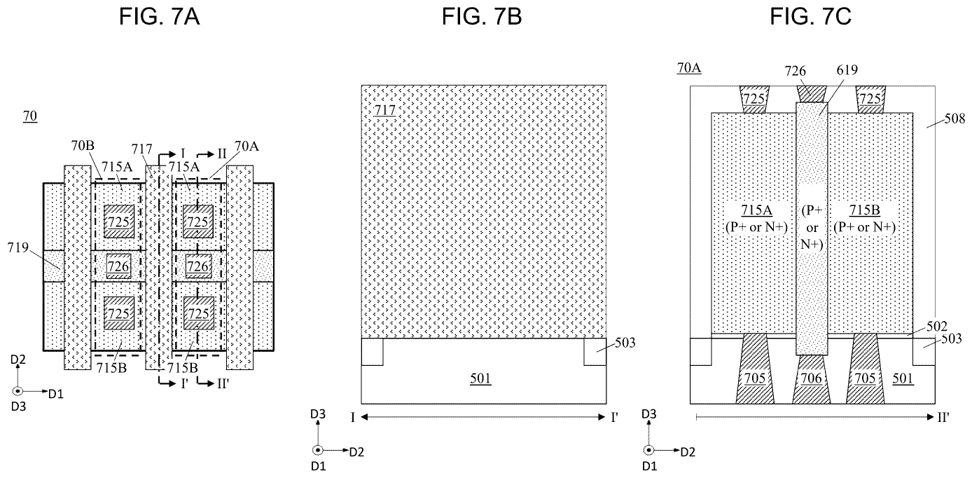

FIGS. 7A-7C illustrate a semiconductor device in a forksheet transistor structure in which BJTs are formed on a backside isolation structure, according to one or more embodiments.

FIG. 7A is a plan view of a semiconductor device 70, FIG. 7B is a cross-section view of the semiconductor device 70 shown in FIG. 7A taken along lines I-I′, and FIG. 7C is a cross-section view of the semiconductor device 70 shown in FIG. 7A taken along lines II-II′. It is to be understood here that FIG. 7A is provided to show a positional relationship between selected structural elements of the semiconductor device 70, and thus, some structural elements such as an isolation structure may not be shown in FIG. 7A.

Referring to FIGS. 7A-7C, the semiconductor device 70 may include a plurality of BJTs, for example, a 1^{st} BJT 70A and a 2^{nd} BJT 70B, on or above the backside isolation structure 501, which may be an extension of the backside isolation structure 501 of the semiconductor devices 50 and 60 shown in FIGS. 5A-5C and FIGS. 6A-6C.

Like the semiconductor device 60, the semiconductor device 70 may also be formed based on a stacked forksheet transistor structure. Further, similar to the 1^{st} BJT 30A and the 2^{nd} BJT 30B of the semiconductor device 30 shown in FIGS. 3A-3C, the 1^{st} BJT 70A and the 2^{nd} BJT 70B may each include a 1^{st} semiconductor layer 715A, a semiconductor wall 719, and a 2^{nd} semiconductor layer 715B on the same backside isolation structure 501. Also, similar to the semiconductor layers 615A, 615B and the semiconductor wall 619 of the semiconductor device 60, the semiconductor layers 715A and 715B may be epitaxial structures of silicon (Si) or silicon germanium (SiGe) grown to form source/drain patterns of stacked forksheet transistors, and the semiconductor wall 719 may be an epitaxial structure of silicon (Si) that has replaced an isolation wall of a dielectric material formed to isolate two nanosheet transistors of each of a 1^{st}-level forksheet transistor and a 2^{nd}-level forksheet transistor that correspond to the 1^{st} forksheet transistor FT1 and the 2^{nd} forksheet transistor FT2 of the semiconductor device 50, respectively. The semiconductor wall 719 may be an extension of the semiconductor wall 619 according to one or more embodiments.

Further, the semiconductor layers 715A, 715B and the semiconductor wall 719 may be formed of the same materials forming the semiconductor layers 315A, 315B and the semiconductor wall 319 of the semiconductor device 30, respectively, and may be polarized in the same manner as the semiconductor layers 315A, 315B and the semiconductor wall 319 are polarized. For example, in a case where both of the semiconductor layers 715A and 715B are of p-type, the semiconductor wall 719 may be of n-type so that the semiconductor layers 715A, 715B and the semiconductor wall 719 can form an emitter, a collector and a base of a PNP BJT, respectively. As another example, in a case where both of the semiconductor layers 715A and 715B are of n-type, the semiconductor wall 719 may be of p-type so that the semiconductor layers 715A, 715B and the semiconductor wall 719 can form an emitter, a collector, and a base of an NPN BJT, respectively. As in the PN diode 60A, for either of the semiconductor layers 715A and 715B to be formed as n-type, the semiconductor layer may be formed of Si with n-type impurities. For either of the semiconductor layers 715A and 715B to be formed as p-type, the semiconductor layer may be formed of SiGe with p-type impurities.

However, unlike the semiconductor layers 315A and 315B of the semiconductor device 30 but like the semiconductor layers 615A and 615B of the semiconductor device 60, each of the semiconductor layers 715A and 715B may be grown from channel layers for two nanosheet transistors at the 1^{st} level and the 2^{nd} level. For example, the 1^{st} semiconductor layer 715A may be grown from channel layers corresponding to the 1^{st} channel layers 510A of the 1^{st} nanosheet transistor T1 and the 3^{rd} channel layers 510C of the 3^{rd} nanosheet transistor T3, and the 2^{nd} semiconductor layer 715B may be grown from channel layers corresponding to the 2^{nd} channel layers 510B of the 2^{nd} nanosheet transistor T2 and the 4^{th} channel layers 510D of the 4^{th} nanosheet transistor T4. Thus, the BJTs 70A and 70B of the semiconductor device 70 may have a larger size in each of the emitter region, the base region and the collector region to improve the device performance.

The BJTs 70A an 70B may also include frontside contact plugs 725 and 726 formed on the semiconductor layers 715A, 715B and the semiconductor wall 719, respectively. Additionally or alternatively, backside contact plugs 705 and 706 may be formed on the semiconductor layers 715A, 715B and the semiconductor wall 719, respectively. For example, the backside contact plugs 705 and 706 may be formed on bottom surfaces of the semiconductor layers 715A, 715B and the semiconductor wall 719, respectively, and the frontside contact plugs 725 and 726 may be formed on top surfaces of the semiconductor layers 715A, 715B and the semiconductor wall 719, respectively. In this case, one of the frontside contact plug and the backside contact plug formed on at least one of the semiconductor layers 715A, 715B and the semiconductor wall 719 may be disabled, for example, by not being connected to a voltage source or any other circuit element. These contact plugs 705, 706, 725 and 726 may function as emitter contacts, base contacts, and collector contacts, respectively.

Thus, even if a backside isolation structure is formed to provide a space for forming a BSPDN structure for stacked forksheet transistors, BJTs may be formed based on semiconductor layers grown to form source/drain patterns of the stacked forksheet transistors and a semiconductor wall that replaces an isolation wall formed for the stacked forksheet transistors.

In the meantime, in the semiconductor device 70, one of the two devices 70A and 70B may be formed as PN diode by controlling polarities of the semiconductor layers 715A and 715B while the other of the two devices 70A and 70B is formed a BJT as described above. For example, in a case where the semiconductor wall 719 is formed as n-type and the semiconductor layers 715A and 715B of the device 70A are formed as p-type to form a PNP BJT, the semiconductor layers 715A and 715B of the device 70B may be formed as p-type and n-type, respectively, and the frontside contact plugs 706 and 726 on the semiconductor wall 719 between these two semiconductor layers 715A and 715B may be disabled. Thus, the semiconductor device 70 may be formed as a combination of a BJT 70A and a PN diode 70B based on a stacked forksheet transistor structure.

In the above embodiments, the semiconductor wall 719 is described as being formed of silicon (Si) doped with p-type impurities or n-type impurities. However, like the semiconductor wall 319 of the semiconductor device 30 shown in FIGS. 3A-3C, the semiconductor wall 719 may be formed of silicon-germanium (SiGe) doped with p-type impurities, while each of the semiconductor layers 715A and 715B may be formed of silicon (Si) doped with n-type impurities. This configuration allows at least one of the BJTs 70A or 70B to function as a heterojunction bipolar transistor (HBT), enabling high-speed carrier transport and improved performance at high frequencies.

As described above in reference to FIGS. 6A-6C and 7A-7C, the stacked forksheet transistor structure formed based on a backside isolation structure is used to form PN diodes and BJTs. However, the stacked forksheet transistor structure is provided to form the stacked forksheet transistors FT1 and FT2 shown in FIGS. 5A-5C according to the original circuit design. Thus, a semiconductor device based on a stacked forksheet transistor structure may be formed to include at least two of the semiconductor devices 50, 60 and 70 and the variant of the semiconductor device 70 including a combination of a BJT and a PN diode as described above. This semiconductor device may also include the same backside isolation structure 501, the same STI structure 503, the same bottom dielectric isolation layer 502, and the same ILD layer 508, as shown in FIGS. 5A-5C, 6A-6C and 7A-7C.

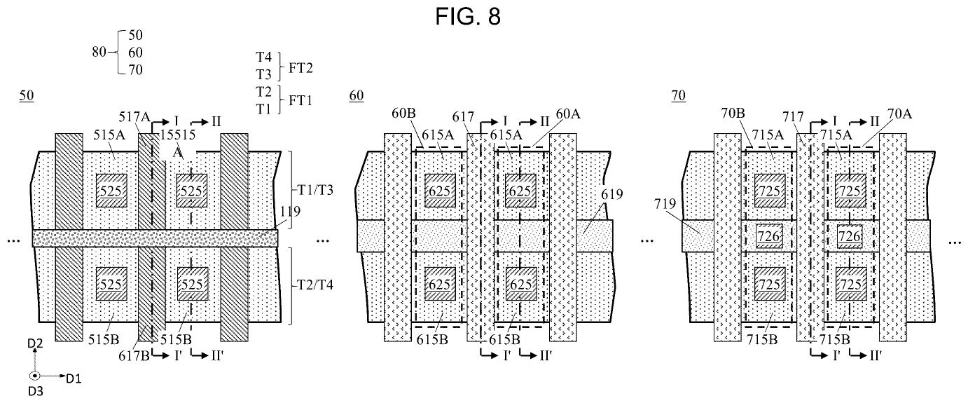

FIG. 8 illustrates a semiconductor device in a stacked forksheet transistor structure in which stacked forksheet transistors, passive devices and BJTs are formed on a backside isolation structure, according to one or more embodiments.

Referring to FIG. 8, a semiconductor device 80 may include the semiconductor device 50 of FIGS. 5A-5C, the semiconductor device 60 of FIGS. 6A-6C, and the semiconductor device 70 of FIGS. 7A-7C formed on a same backside isolation structure which has replaced a same substrate.

As the semiconductor devices 50, 60 and 70 including the stacked forksheet transistors FT1, FT2, the PN diodes 60A, 60B and the BJTs 70A, 70B can be formed based on the same substrate, separate formation of the passive devices and the BJTs using one or more different substrates may be avoided to achieve a device density and manufacturing efficiency.

FIG. 8 shows that the semiconductor devices 50-70 are arranged in the D1 direction. However, the disclosure is not limited there to. According to one or more other embodiments, the semiconductor devices 50-70 may be arranged in the D2 direction or may be formed at different positions to form the semiconductor device 80 in a stacked forksheet transistor structure in which one or more stacked forksheet transistors, one or more PN diodes and one or more BJTs are formed. Moreover, the variants of the semiconductor device 70 discussed above in reference to FIGS. 7A-7C may also be included in the semiconductor device 80.

Herebelow, a method of manufacturing a semiconductor device in a forksheet transistor structure including passive devices and a backside isolation structure is provided.

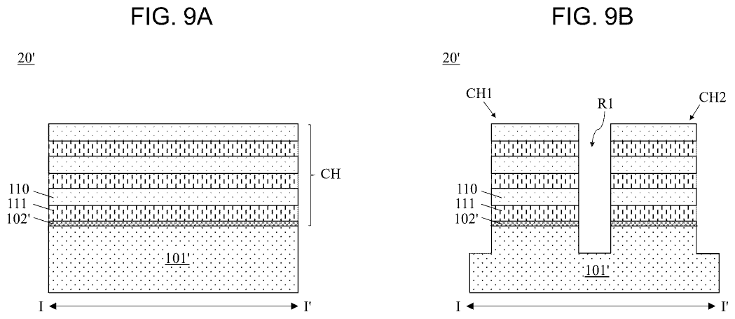

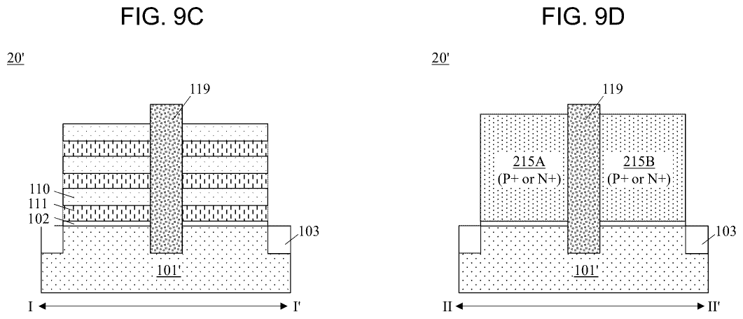

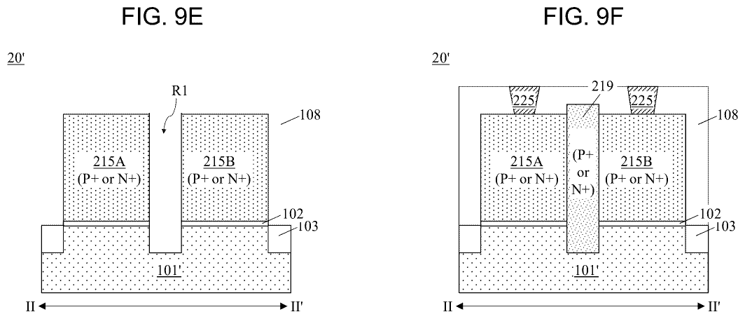

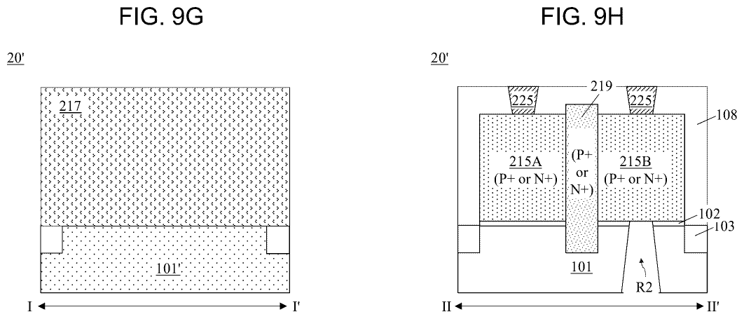

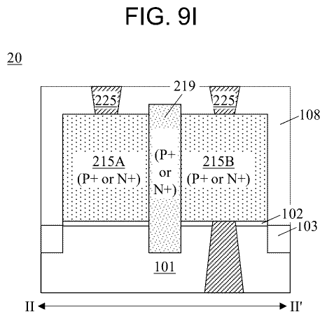

FIGS. 9A through 9I illustrate cross-section views of intermediate semiconductor devices after respective steps of manufacturing a semiconductor device in a forksheet transistor structure in which passive devices are formed on a backside isolation structure, according to one or more embodiments.

The semiconductor device manufactured through the respective steps may be or correspond to the semiconductor device 20 shown in FIGS. 2A-2C, and thus, the cross-section views of the intermediate semiconductor devices may correspond to those shown in FIG. 2B or 2C taken along lines I-I′ or II-II′, respectively. Further, duplicate descriptions about the same structural elements described above in reference to FIGS. 2A-2C may be omitted and the same reference characters or numerals may be used herebelow for brevity purposes.

Referring to FIG. 9A, which is a cross-section view corresponding to that taken along lines I-I′ of FIG. 2A, an intermediate semiconductor device 20′ including a channel stack CH formed on a substrate 101′ may be provided.

The channel stack CH may be formed by epitaxially growing a plurality of nanosheet layers from the substrate 101′ in the D3 direction through, for example, molecular beam epitaxy (MBE), vapor-phase epitaxy (VPE), etc., not being limited thereto. The substrate 101′ may be formed of a group IV semiconductor (e.g., Si), a group III-V compound semiconductor, or a group II-VI compound semiconductor, not being limited thereto.

To form the channel stack CH on the substrate 101′, a sacrificial layer 111 of silicon germanium (SiGe) and a channel layer 110 of silicon (Si) may be epitaxially grown one after another in an alternating manner until a desired number of layers are obtained. Prior to the formation of the sacrificial layers 111 and the channel layers 110, a bottom sacrificial layer 102′ formed of SiGe may be first epitaxially grown from the substrate 101′.

A Ge concentration in SiGe of the bottom sacrificial layer 102′ may be greater than that of the sacrificial layers 111 to provide etch selectivity therebetween for a selective patterning operation in a later step. For example, the bottom sacrificial layer 102′ may have a Ge concentration of 40-50%, while the sacrificial layers 111 may have a Ge concentration of 25-30%, not being limited thereto.

Referring to FIG. 9B, which is a cross-section view corresponding to that taken along lines I-I′ of FIG. 2A, the channel stack CH may be etched back in the middle to form a 1^{st} channel stack CH1 and a 2^{nd} channel stack CH2 with a 1^{st} recess R1 therebetween.

The 1^{st} recess R1 may be formed to penetrate the channel stack CH from top into the substrate 101′ to a predetermined depth. In a next step, the 1^{st} recess R1 may be filled in with an isolation wall which is to isolate two nanosheet transistors to be formed from the two channel stacks CH1 and CH2. As the channel stack CH is divided by the 1^{st} recess R1 along the D1 direction, the bottom sacrificial layer 102′, the sacrificial layers 111 and the channel layers 110 may also be divided along the D1 direction to respectively form the two channel stacks CH1 and CH2.

The etching operation performed in this step may include dry etching based on hard mask patterns formed on a top surface of the intermediate semiconductor device 20′.

At around this step, a dummy gate structure may be formed to surround the channel stacks CH1 and CH2 to protect the channel stacks CH1 and CH2 in the subsequent etching and deposition operations until a gate structure replaces the dummy gate structure in a later step.

Referring to FIG. 9C, which is a cross-section view corresponding to that taken along lines I-I′ of FIG. 2A, an isolation wall 119 may be formed in the 1^{st} recess R1 obtained in the previous step.

The isolation wall 119 may be formed in the 1^{st} recess R1 by depositing a dielectric material such as silicon nitride (Si₃N₄), silicon oxide (e.g., SiO₂), silicon oxynitride (SiON), etc. through, for example, physical vapor deposition (PVD), chemical vapor deposition (CVD), plasma enhanced chemical vapor deposition (PECVD), or combinations thereof, not being limited thereto.

Further, the substrate 101′ may be patterned at an upper-left corner and an upper-right corner to form shallow trenches filled in a dielectric material such as silicon oxide (SiO₂), to form shallow trench isolation (STI) structures 103. Also, the bottom sacrificial layer 102′ may be selectively removed against the channel layers 110 and the sacrificial layers 111, and replaced by a bottom dielectric isolation layer 102.

At around this step, the channel stacks CH1 and CH2 surrounded by the dummy gate structure may be patterned to provide spaces for formation of source/drain patterns for one or more forksheet transistors and semiconductor layers for one or more PN devices or BJTs in a next step.

Referring to FIG. 9D, which is a cross-section view corresponding to that taken along lines II-II′ of FIG. 2A, a 1^{st} semiconductor layer 215A and a 2^{nd} semiconductor layer 215B may be formed on the substrate 101′.

The semiconductor layers 215A and 215B may be epitaxially grown from the channel layers 110 included in the channel stacks CH1 and CH2, respectively, through, for example, MBE, VPE, etc. Subject to a circuit design, each of the semiconductor layers 215A and 215B may be formed of Si or SiGe. Further, the semiconductor layers 215A and 215B may be in-situ doped with p-type impurities (e.g., boron, gallium, indium, etc.) or n-type impurities (e.g., phosphorus, arsenic, antimony, etc.) according to the circuit design.

For example, each of the semiconductor layers 215A and 215B may be formed of Si with n-type impurities doped therein to be an n-type region of a PN diode or a BJT, or SiGe with p-type impurities doped therein to be a p-type region of the PN diode or the BJT.

At around this step, the dummy gate structures surrounding the channel stacks CH1 and CH2 as described in reference to FIG. 9B and the sacrificial layers 111 formed in the channel stacks CH1 and CH2 may be removed and replaced by gate structures like the gate structures 117A and 117B shown in FIGS. 1A-1C. Thus, the channel layers 110 may be surrounded by the gate structures.

Referring to FIG. 9E, which is a cross-section view corresponding to that taken along lines II-II′ of FIG. 2A, the isolation wall 119 may be removed in the intermediate semiconductor device 20′ to reopen the 1^{st} recess R1.

Here, it is understood that, in a case where the semiconductor device 40 including the semiconductor devices 10-30 is to be formed, the isolation wall 119 may be removed only in intermediate semiconductor devices including the intermediate semiconductor device 20′ which are to form the semiconductor device 20 shown in FIGS. 2A-2C and the semiconductor device 30 shown in FIGS. 3A-3C. Thus, in manufacturing the semiconductor device 40, the isolation wall 119 formed in an intermediate semiconductor device to form the semiconductor device 10 may not be removed because this isolation wall 119 is to isolate the two nanosheet transistors T1 and T2 to form the forksheet transistor FT when the intermediate semiconductor device is completed as the semiconductor device 10.

The removal of the isolation wall 119 formed of, for example, silicon nitride may be performed through, for example, dry etching or wet etching using an etchant such as hot phosphoric acid, not being limited thereto, that selectively etches silicon nitride against silicon (Si) and silicon germanium (SiGe) forming the semiconductor layers 215A and 215B.

As the isolation wall 119 penetrating the substrate 101′ is removed to reopen the 1^{st} recess R1, the substrate 101 may be exposed through the 1^{st} recess R1 again such that a bottom of the 1^{st} recess R1 may be at a level below a top surface of the substrate 101′ on the bottom dielectric isolation layer 102.

In this step, the 1^{st} recess R1 may be further recessed to have a greater width so that a depletion region to be formed in this recess may have a greater width to increase a device performance of a PN diode or a BJT to be formed from the intermediate semiconductor device 20′.

Referring to FIG. 9F, which is a cross-section view corresponding to that taken along lines II-II′ of FIG. 2A, a semiconductor wall 219 may be formed in the 1^{st} recess R1, an ILD layer 108 may be formed to surround the semiconductor layers 215A and 215B, and frontside contact plugs 225 may be formed on the semiconductor layers 215A and 215B.

The semiconductor wall 219 of silicon (Si) may be epitaxially grown from inside the substrate 101 exposed through the 1^{st} recess R1, and may be in-situ doped with p-type impurities or n-type impurities subject to a circuit design.

For example, in a case where the 1^{st} semiconductor layer 215A is formed as a p-type region and the 2^{nd} semiconductor layer 215B is formed as an n-type region, the semiconductor layer 219 may be doped with either p-type impurities or n-type impurities to form the 1^{st} semiconductor layer 215A, the semiconductor wall 219 and the 2^{nd} semiconductor layer 215B as a PN diode.

Also in this step, the ILD layer 108 may be formed to surround the semiconductor layers 215A and 215B through, for example, PVD, CVD, PECVD, or a combination thereof of a low-k dielectric material such as silicon oxide (e.g., SiO₂), not being limited thereto, followed by planarization on top. In addition, the frontside contact plugs 225 may be formed on top surfaces of the semiconductor layers 215A and 215B, respectively, through dry etching or wet etching on the ILD layer 108 followed by deposition of a metal or metal compound in a space provided by the ILD etching.

Referring to FIG. 9G, which is a cross-section view corresponding to that taken along lines I-I′ of FIG. 2A, a diffusion break structure 217 may be formed to isolate the PN diode formed by the semiconductor layers 215A, 215B and the semiconductor wall 219 from another PN diode or a BJT at a side along the D1 direction.

Diffusion break structures including the diffusion break structure 217 may be formed by removing the gate structures and the channel layers 110 surrounded by the gate structures as described above in reference to FIG. 9D. At this time, portions of the semiconductor wall 219 between the gate structure (corresponding to the gate structure 117A) at a side of the 1^{st} semiconductor layer 215A and the gate structure (corresponding to the gate structure 117B) at a side of the 2^{nd} semiconductor layer 215B may also be removed so that the diffusion break structure 217 isolate the PN diode formed by the semiconductor layers 215A, 215B and the semiconductor wall 219 from another PN diode as shown in FIG. 2A or a BJT at a side of the PN diode along the D1 direction. For example, FIG. 2A shows that the 1^{st} PN diode 20A and the 2^{nd} PN diode 20B are isolated from each other by the diffusion break structure 217.

Referring to FIG. 9H, which is a cross-section view corresponding to that taken along lines II-II′ of FIG. 2A, a backside process may be performed on the intermediate semiconductor device 20′ to form a backside isolation structure 101 by replacing the substrate 101′.

The substrate 101′ may be removed by mechanical grinding or dry etching, and then the backside isolation structures of a low-k dielectric material such as silicon oxide (e.g., SiO₂) may be formed in a space provided by the removal of the substrate 101′ through, for example, PVD, CVD, PECVD, or a combination thereof, not being limited thereto.

The backside process may also include formation of a 2^{nd} recess R2 in the backside isolation structure 101 to expose a bottom surface of the 2^{nd} semiconductor layer 215B. The 2^{nd} recess R2 may be formed through, for example, dry etching or wet etching.

The backside process performed in this step may be performed after flipping upside down the intermediate semiconductor device 20′obtained in the previous step.

Referring to FIG. 91, which is a cross-section view corresponding to that taken along lines II-II′ of FIG. 2A, the 2^{nd} recess R2 may be filled in with a backside contact plug 205.

The backside contact plug 205 may be formed in the 2^{nd} recess R2 to be connected to the bottom surface of the 2^{nd} semiconductor layer 215B. The backside contact plug 205 may function as an anode contact or a cathode contact of the 2^{nd} semiconductor layer 215B when the frontside contact plug 225 on the top surface of the 2^{nd} semiconductor layer 215B is disabled.

The formation of the backside contact plug 205 in the 2^{nd} recess R2 may be performed by depositing a metal or a metal compound therein through, for example, PVD, CVD, PECVD, or a combination thereof, not being limited thereto.

Through the above-described process of FIGS. 9A-9I, the PN diodes 20A and 20B shown in FIGS. 2A-2C may be manufactured based on the forksheet transistor structure. The BJTs 30A and 30B shown in FIGS. 3A-3C may also be manufactured through the same steps described above except that polarities of the semiconductor layers 315A, 315B and the semiconductor wall 319 are differently controlled through epitaxy and in-situ doping.

It is also understood that the above-described process of manufacturing the semiconductor device 20 in reference to FIGS. 9A-9I may be a part of a process of manufacturing the semiconductor device 40 based on the same substrate 101′ which is replaced by the same backside isolation structure 101.

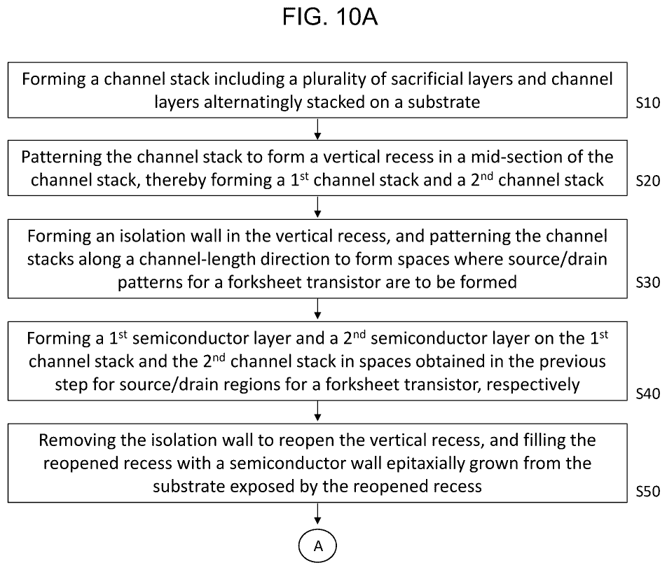

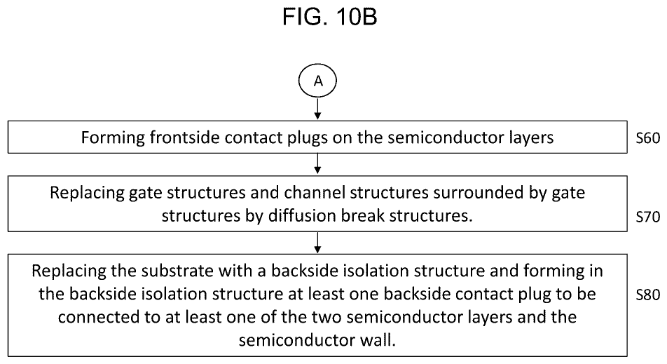

FIGS. 10A and 10B illustrate a flowchart of a method of manufacturing a semiconductor device in a forksheet transistor structure including a passive device or a BJT on a backside isolation structure, according to one or more embodiments.

In step S10, a channel stack including a plurality of nanosheet layers may be formed on a substrate. The nanosheet layers may include a plurality of sacrificial layers and channel layers alternatingly stacked on the substrate. The sacrificial layers may be formed of silicon germanium (SiGe) while the channel layers may be formed of silicon (Si).

In step S20, the channel stack may be patterned and divided by forming a vertical recess in a mid-section of the channel stack, thereby forming a 1^{st} channel stack (left channel stack) and a 2^{nd} channel stack (right channel stack). The vertical recess may penetrate the channel stack in a vertical direction (D3 direction) into the substrate to a predetermined depth and extended in a channel-length direction in the vertical recess.

In this step, a dummy gate structure may be formed to surround the channel stacks to protect the channel stacks in the subsequent etching and deposition operations until a gate structure replaces the dummy gate structure in a later step

In step S30, an isolation wall may be formed in the vertical recess, and the 1^{st} channel stack and the 2^{nd} channel stack may be patterned along a channel-length direction (D1 direction) to form spaces where source/drain patterns for a forksheet transistor are to be formed. By the patterning of the channel stacks, channel structures for the forksheet transistors may remain surrounded by the dummy gate structures.

In step S40, a 1^{st} semiconductor layer and a 2^{nd} semiconductor layer may be formed on the 1^{st} channel stack and the 2^{nd} channel stack in spaces obtained in the previous step for source/drain regions for a forksheet transistor, respectively. The two semiconductor layers may be formed of silicon (Si) or silicon germanium (SiGe) epitaxially grown from the two channel stacks, and may be doped with p-type impurities or n-type impurities. The two semiconductor layers may be isolated from each other by the isolation wall.

In this step, the dummy gate structures surrounding the channel stacks as described above and the sacrificial layers formed in the channel stacks may be removed and replaced by gate structures, and thus, channel layers included in the channel structures may be surrounded by the gate structures.

In step S50, the isolation wall may be removed to reopen the vertical recess, and the reopened recess may be filled in with a semiconductor wall epitaxially grown from the substrate exposed by the reopened recess. The semiconductor wall may be formed of silicon (Si) or silicon germanium (SiGe) doped with p-type impurities or n-type impurities so that the 1^{st} semiconductor layer, the semiconductor wall, and the 2^{nd} semiconductor layer may form a PN diode or a BJT.

In step S60, frontside contact plugs may be formed on the semiconductor layers to form an anode contact and a cathode contact, respectively, for a PN device, or may be formed on the semiconductor layers as well as the semiconductor wall to form an emitter contact, a collector contact and a base contact, respectively, for a BJT,

In step S70, the gate structures and the channel structures surrounded by gate structures may be replaced by diffusion break structures which isolate the PN diode or the BJT formed by the semiconductor layers and the semiconductor wall from another PN diode or another BJT.

In step S80, the substrate may be replaced by a backside isolation structure and at least one backside contact plug may be formed in the backside isolation structure to be connected to at least one of the two semiconductor layers and the semiconductor wall. One of a frontside contact plug and a backside contact plug connected to each of the semiconductor layers and the semiconductor wall may be disabled when the other is connected to a voltage source or another circuit element in a semiconductor device.

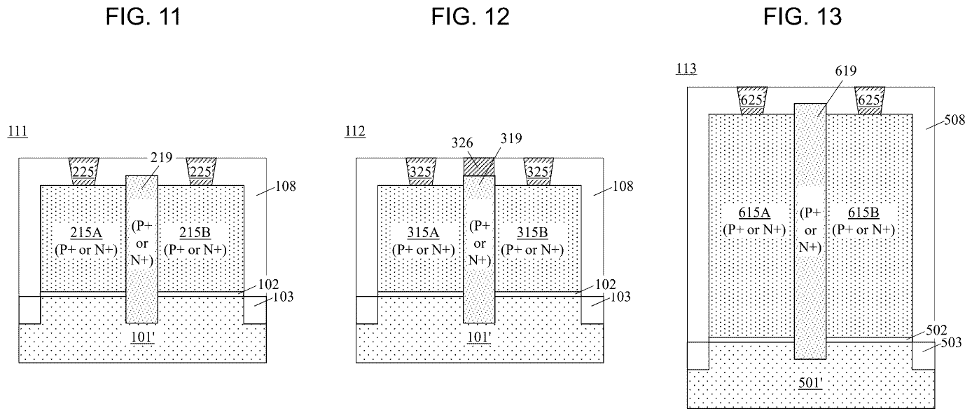

In the above embodiments, a forksheet transistor structure including a BSPDN structure is used to form PN diodes and the BJTs on the front side of the forksheet transistor. For example, an isolation wall for a forksheet transistor is replaced with a semiconductor wall as a p-type or n-type region of a PN diode or a base of a BJT, and further, source/drain patterns for the forksheet transistor are formed as semiconductor layers of a p-type or n-type region of the PN diode or an emitter and a collector of the BJT. This formation of the PN diodes and the BJTs on the front side of the forksheet transistor is introduced because the back side thereof is formed of a backside isolation structure of silicon oxide where the PN diodes and the BJTs cannot be formed. However, the disclosure is not limited thereto. According to one or more other embodiments, PN diodes and BJTs may also be formed on the foregoing manner on the front side of the forksheet transistor structure even when a substrate, for example, formed of silicon, is not replaced by the backside isolation structure, as shown in FIGS. 11-13.

FIG. 11 illustrates a semiconductor device in a forksheet transistor structure in which a passive device is formed on a substrate, according to one or more embodiments. FIG. 12 illustrates a semiconductor device in a forksheet transistor structure in which a BJT is formed on a substrate, according to one or more embodiments. FIG. 13 illustrates a semiconductor device in a stacked forksheet transistor structure in which a passive device is formed on a substrate, according to one or more embodiments.

Referring to FIG. 11, a semiconductor device 11 which corresponds to the semiconductor device 20 shown in FIGS. 2A-2C, a PN diode which is the same as the PN diode 20A (FIG. 2C) may be formed on a substrate 101′ which is not replaced by a backside isolation structure.

Referring to FIG. 12, a semiconductor device 12 which corresponds to the semiconductor device 30 shown in FIGS. 3A-3C, a BJT which is the same as the BJT 30A (FIG. 3C) may be formed on a substrate 101′, which may be the same as the substrate 101′ of the semiconductor device 11 of FIG. 11.

Referring to FIG. 13, a semiconductor device 13 which corresponds to the semiconductor device 60 shown in FIGS. 6A-6C, a PN diode which is the same as the PN diode 60A (FIG. 6C) may be formed on a substrate 501′.

It is understood here that the semiconductor devices 11-13 are formed on the respective substrates only without being replaced by the corresponding backside isolation structures, and thus, various structural combinations and variants described above in reference to FIGS. 1A-1C to FIGS. 10A-10B may also apply to the semiconductor devices 11-13.

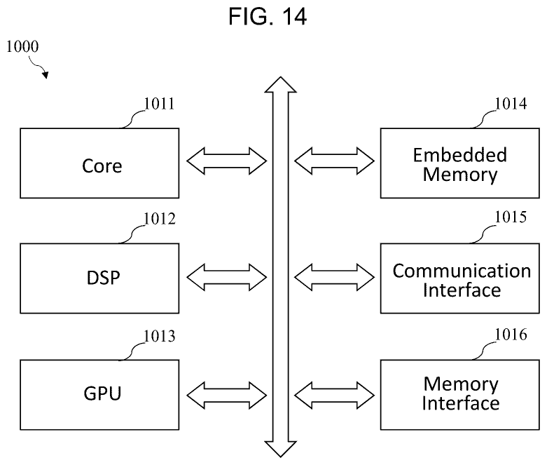

FIG. 14 is a schematic block diagram illustrating an electronic device including a semiconductor device in a forksheet transistor structure in which at least one of a passive device and a BJT is formed, according to one or more embodiments. This semiconductor device may be one of the semiconductor devices described above in reference to FIGS. 1A-1C to FIG. 8 and FIGS. 11-13.

Referring to FIG. 14, an SoC 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1007.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (DRAM), a flash memory, etc.

At least one of the core 1011, the DSP 1012, the GPU 1013, and/or the embedded memory 1014 may include one or more of the semiconductor devices described above in reference to FIGS. 1A-1C to FIG. 8 and FIGS. 11-13, according to one or more embodiments.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

1. A semiconductor device comprising:
a semiconductor wall having a 1^{st} polarity;
a 1^{st} semiconductor layer on a 1^{st} side of the semiconductor wall along a 2^{nd} direction intersecting a 1^{st} direction, the 1^{st} semiconductor layer having the 1^{st} polarity or a 2^{nd} polarity opposite to the 1^{st} polarity; and
a backside isolation structure below the semiconductor wall and the 1^{st} semiconductor layer along a 3^{rd} direction intersecting the 1^{st} direction and the 2^{nd} direction,
wherein the backside isolation structure comprises a 1^{st} insulation material.

2. The semiconductor device of claim 1, further comprising a backside contact plug on the 1^{st} semiconductor layer or the semiconductor wall, the backside contact plug in the backside isolation structure comprising a conductive material.

3. The semiconductor device of claim 2, further comprising a frontside contact plug on the 1^{st} semiconductor layer or the semiconductor wall, the frontside contact plug above the backside isolation structure along the 3^{rd} direction comprising a conductive material.

4. The semiconductor device of claim 1, further comprising a 2^{nd} semiconductor layer on a 2^{nd} side of the semiconductor wall opposite to the 1^{st} side along the 2^{nd} direction, the 2^{nd} semiconductor layer having the 1^{st} polarity or the 2^{nd} polarity.

5. The semiconductor device of claim 4, wherein the semiconductor wall comprises silicon germanium and p-type impurities, and
wherein the 1^{st} semiconductor layer and the 2^{nd} semiconductor layer comprise silicon and n-type impurities.

6. The semiconductor device of claim 4, further comprising a backside contact plug on the 1^{st} semiconductor layer, the 2^{nd} semiconductor layer, or the semiconductor wall, the backside contact plug in the backside isolation structure comprising a conductive material.

7. The semiconductor device of claim 1, further comprising a 1^{st} forksheet transistor on the backside isolation structure,
wherein the 1^{st} forksheet transistor comprising a 1^{st} field-effect transistor, a 2^{nd} field-effect transistor, and an isolation wall between the 1^{st} field-effect transistor and the 2^{nd} field-effect transistor.

8. The semiconductor device of claim 7, wherein a source/drain pattern of the 1^{st} field-effect transistor and the 1^{st} semiconductor layer have the same height along the 3^{rd} direction.

9. The semiconductor device of claim 7, further comprising a 2^{nd} forksheet transistor above the 1^{st} forksheet transistor along the 3^{rd} direction,
wherein the 2^{nd} forksheet transistor comprising a 3^{rd} field-effect transistor and a 4^{th} field-effect transistor isolated with the isolation wall therebetween.

10. The semiconductor device of claim 7, further comprising:
a 2^{nd} semiconductor layer on a side of the 1^{st} semiconductor layer along the 1^{st} direction; and
a diffusion break structure comprising a 2^{nd} insulation material between the 1^{st} semiconductor layer and the 2^{nd} semiconductor layer,
wherein the 2^{nd} insulation material is the same as or different from the 1^{st} insulation material.

11. The semiconductor device of claim 1, further comprising:
a 2^{nd} semiconductor layer on a side of the 1^{st} semiconductor layer along the 1^{st} direction; and
a diffusion break structure comprising a 2^{nd} insulation material between the 1^{st} semiconductor layer and the 2^{nd} semiconductor layer,
wherein the 2^{nd} insulation material is the same as or different from the 1^{st} insulation material.

12. A semiconductor device comprising:
a semiconductor wall having a 1^{st} polarity;
a 1^{st} semiconductor layer on a 1^{st} side of the semiconductor wall along a 2^{nd} direction intersecting a 1^{st} direction, the 1^{st} semiconductor layer having the 1^{st} polarity or a 2^{nd} polarity opposite to the 1^{st} polarity; and
a diffusion break structure comprising a 1^{st} insulation material at a side of the 1^{st} semiconductor layer and the semiconductor wall along the 1^{st} direction.

13. The semiconductor device of claim 12, further comprising a backside isolation structure below the semiconductor wall, the 1^{st} semiconductor layer, and the diffusion break structure along a 3^{rd} direction intersecting the 1^{st} direction and the 2^{nd} direction,
wherein the backside isolation structure comprises a 2^{nd} insulation material which are the same as or different from the 1^{st} insulation material.

14. The semiconductor device of claim 13, further comprising a backside contact plug on the 1^{st} semiconductor layer or the semiconductor wall, the backside contact plug in the backside isolation structure comprising a conductive material.

15. The semiconductor device of claim 14, further comprising a frontside contact plug on the 1^{st} semiconductor layer or the semiconductor wall, the frontside contact plug above the backside isolation structure along the 3^{rd} direction comprising a conductive material.

16. The semiconductor device of claim 12, further comprising a 2^{nd} semiconductor layer on a 2^{nd} side of the semiconductor wall opposite to the 1^{st} side along the 2^{nd} direction, the 2^{nd} semiconductor layer having the 1^{st} polarity or the 2^{nd} polarity.

17. The semiconductor device of claim 16, further comprising a 3^{rd} semiconductor layer having the 1^{st} polarity or the 2^{nd} polarity,
wherein the diffusion break structure is between the 1^{st} semiconductor layer and the 3^{rd} semiconductor layer along the 1^{st} direction.

18. A method of manufacturing a semiconductor device, the method comprising:
forming a 1^{st} semiconductor layer having a 1^{st} polarity or a 2^{nd} polarity opposite to the 1^{st} polarity;
forming a semiconductor wall having the 1^{st} polarity at a side of the 1^{st} semiconductor layer along a 2^{nd} direction intersecting a 1^{st} direction; and
forming a backside isolation structure below the semiconductor wall and the 1^{st} semiconductor layer along a 3^{rd} direction intersecting the 1^{st} direction and the 2^{nd} direction,
wherein the backside isolation structure comprises a 1^{st} insulation material.

19. The method of claim 18, further comprising forming, in the backside isolation structure, a backside contact plug connected to the 1^{st} semiconductor layer or the semiconductor wall, the backside contact plug comprising a conductive material.

20. The method of claim 18, further comprising forming a 2^{nd} semiconductor layer on a side of the semiconductor wall opposite to the 1^{st} semiconductor layer along the 2^{nd} direction, the 2^{nd} semiconductor layer having the 1^{st} polarity or the 2^{nd} polarity.

21-29. (canceled)
